(19) United States
(12) Patent Application Publication
(10) Pub. No.: US 2009/0256931 A1
(43) Pub. Date: Oct. 15, 2009

(54) Camera module, method of manufacturing the same, and electronic system having the same

(75) Inventors: Chung-Sun Lee, Gunpo-si (KR); Yong-Hwan Kwon, Suwon-si (KR); Un-Byoung Kang, Hwaseong-si (KR); Hyuek-Jae Lee, Suwon-si (KR); Woon-Seong Kwon, Seoul (KR); Hyung-Sun Jang, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/381,489

(22) Filed: Mar. 12, 2009

(30) Foreign Application Priority Data
Apr. 11, 2008 (KR) 10-2008-0033544

(51) Int. Cl. H04N 5/76; H01L 21/50; H04N 5/225

(52) U.S. Cl. 348/231.99; 438/64; 348/340; 438/68; 257/E21.499; 348/E05.024; 348/E05.031

(57) ABSTRACT

A camera module, a method of manufacturing the same, and an electronic system having the same are provided. The camera module includes an image sensor chip having an active plane and a backside, a ground wiring extending from a sidewall of the image sensor chip to the backside, a lens structure having a light detector with at least one lens stacked on the active plane, and a conductive housing extending to the ground wiring along with an outer wall of the lens structure excluding the light detector.

### CROSS-REFERENCE TO RELATED APPLICATION

This application claims the benefit of Korean Patent Application No. 10-2008-0033544, filed Apr. 11, 2008, the contents of which are hereby incorporated herein by reference in their entirety.

### FIELD OF INVENTION

Exemplary embodiments relate to a camera module, a method of manufacturing the same, and an electronic system having the same.

### BACKGROUND

With the addition of a camera function in mobile phones, as well as portable digital cameras, demand for subminiature camera modules having high image quality is increasing. A subminiature camera module is stacked on an image sensor chip including a complementary metal oxide semiconductor (CMOS) or a charge-coupled device (CCD) image sensor and designed to have a lens structure including at least one lens. The performance of the camera module may be degraded due to various factors. Camera malfunction and image defects can be caused by a number of factors, including electromagnetic interference (EMI), which results when external electromagnetic waves enter the camera module without being filtered and cause the image sensor chip to malfunction.

### SUMMARY

Aspects of the present invention relate to a camera module having a compact structure for stopping EMI.

Aspects of the present invention also relate to a method of manufacturing a camera module having a compact structure for stopping EMI.

Aspects of the present invention also relate to an electronic system including a camera module that has a compact structure for stopping EMI.

According to an exemplary embodiment, a camera module includes: an image sensor chip having an active plane and a backside; a ground wiring extending from a sidewall of the image sensor chip to the backside; a lens structure having a light detector with at least one lens stacked on the active plane; and a conductive housing extending to the ground wiring along with an outer wall of the lens structure excluding the light detector.

The sidewall of the image sensor chip can be inclined to have a width that gradually narrows from the active plane to the backside.

The image sensor chip can have chip pads on the active plane, and vias electrically connected to the chip pads through the image sensor chip. The ground wiring can be formed to be electrically connected to some of the vias.

The camera module can further comprise conductive balls disposed on lower portions of the ground wirings formed on the backsides of the image sensor chips.

The camera module can further comprise a redistribution structure formed on backsides of image sensor chips, wherein the ground wiring of the backside is formed at the same level as the redistribution structure.

The camera module can further comprise an adhesion layer having an opening formed on the active plane, and a filter substrate disposed on the adhesion layer, wherein the filter substrate has a filter circuit electrically connected to a circuit formed on the active plane.

According to an exemplary embodiment, a method of manufacturing a camera module includes: forming an image sensor chip having an active plane and a backside; forming a ground wiring extending from a sidewall of the image sensor chip to the backside; forming a lens structure having a light detector with at least one lens stacked on the active plane; and forming a conductive housing extending to the ground wiring along with an outer wall of the lens structure excluding the light detector.

The sidewall of the image sensor chip can be inclined to have a width that gradually narrows from the active plane to the backside.

The image sensor chip can have chip pads on the active plane, and vias electrically connected to the chip pads through the image sensor chip, and wherein the ground wiring is formed to be electrically connected to some of the vias.

The method can further comprise forming at least one conductive ball on a lower portion of the ground wiring formed on the backside before forming the lens structure.

A redistribution structure can be formed on the backside while forming the ground wiring.

The conductive housing can be formed of at least one material selected from the group consisting of titanium, chrome, titanium tungsten, aluminum, nickel, copper, and silver.

The method can further comprise forming an adhesion layer having an opening on the active plane before forming the lens structure and forming a filter substrate on the adhesion layer. The filter substrate can have a filter circuit electrically connected to a circuit formed on the active plane.

According to another exemplary embodiment, a method of manufacturing a camera module includes: providing a chip wafer having an active plane including main regions and sawing regions, and a backside; forming a preliminary filter structure onto the active plane; forming image sensor chips whose sidewalls are exposed by cutting the backside corresponding to the sawing regions; forming ground wirings extending from the sidewalls of the image sensor chips to backsides of the image sensor chips; forming a preliminary lens structure covering active planes of the image sensor chips and having light detectors with stacked lenses respectively overlapping the main regions of the image sensor chips; separating the image sensor chips by cutting the preliminary filter structure and the preliminary lens structure; and forming filter structures and lens structures that are sequentially stacked on each of the image sensor chips, and forming conductive housings extending to outer walls of the lens structures, excluding the light detectors, the filter structures, and the ground wirings.

The exposed sidewall of each of the image sensor chips can be inclined to have a width that gradually narrows from the active plane to the backside.

Each of the image sensor chips can have chip pads on the active plane, and vias electrically connected to the chip pads through the image sensor chip. Each ground wiring can be formed to be electrically connected to some of the vias.

The method can further comprise forming conductive balls on lower portions of the ground wirings formed on the backsides of the image sensor chips before forming the preliminary lens structure.

A redistribution structure can be formed on the backsides of the image sensor chips while forming the ground wirings.

The preliminary filter structure can have an adhesion layer with an opening on the active plane, and a transparent filter wafer on the adhesion layer, wherein the transparent filter wafer has filter circuits electrically connected to circuits formed on the active planes.

According to an exemplary embodiment, an electronic system includes: a camera module that captures an image; a processor that processes the captured image; a memory unit that stores the processed image data; and an input/output device that communicates with the processor. Here, the camera module includes an image sensor chip having an active plane and a backside, a ground wiring extending from a sidewall of the image sensor chip to the backside, a lens structure having a light detector with at least one lens stacked on the active plane, and a conductive housing extending to the ground wiring along with an outer wall of the lens structure excluding the light detector.

### BRIEF DESCRIPTION OF THE DRAWINGS

Exemplary embodiments are described in further detail below with reference to the accompanying drawings. It should be understood that various aspects of the drawings may have been exaggerated for clarity:

FIG. 1 is a cross-sectional view of an exemplary embodiment of a camera module according to aspects of the present invention;

FIG. 2 is a cross-sectional view of an exemplary embodiment of a camera module according to other aspects of the present invention;

FIG. 3 is a plan view of an exemplary embodiment of a transparent filter substrate according to aspects of the present invention;

FIG. 4 is a schematic block diagram of an exemplary embodiment of an electronic system adopting the camera module according to aspects of the present invention; and

FIGS. 5 to 9 are cross-sectional views showing an exemplary embodiment of a method of manufacturing the camera module according to aspects of the present invention.

### DETAILED DESCRIPTION OF THE EMBODIMENTS

Various exemplary embodiments will now be described more fully with reference to the accompanying drawings. In the drawings, the thicknesses of layers and regions may be exaggerated for clarity.

Detailed illustrative embodiments are disclosed herein. However, specific structural and functional details disclosed herein are merely representative for purposes of describing exemplary embodiments. The invention, however, may be embodied in many alternate forms and should not be construed as limited to only the exemplary embodiments set forth herein.

Accordingly, while exemplary embodiments are capable of various modifications and alternative forms, embodiments thereof are shown by way of example in the drawings and will herein be described in detail. It should be understood, however, that there is no intent to limit exemplary embodiments to the particular forms disclosed, but on the contrary, exemplary embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of exemplary embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof. Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Exemplary embodiments, and intermediate structures, are described herein with reference to cross-sectional illustrations. As such, variations from the shapes of the illustrations as a result, for example, of manufacturing techniques and/or tolerances, may be expected. Thus, exemplary embodiments should not be construed as limited to the particular shapes of regions illustrated herein, but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe exemplary embodiments, various aspects will be described in detail with reference to the attached drawings. However, the present invention is not limited to exemplary embodiments described.

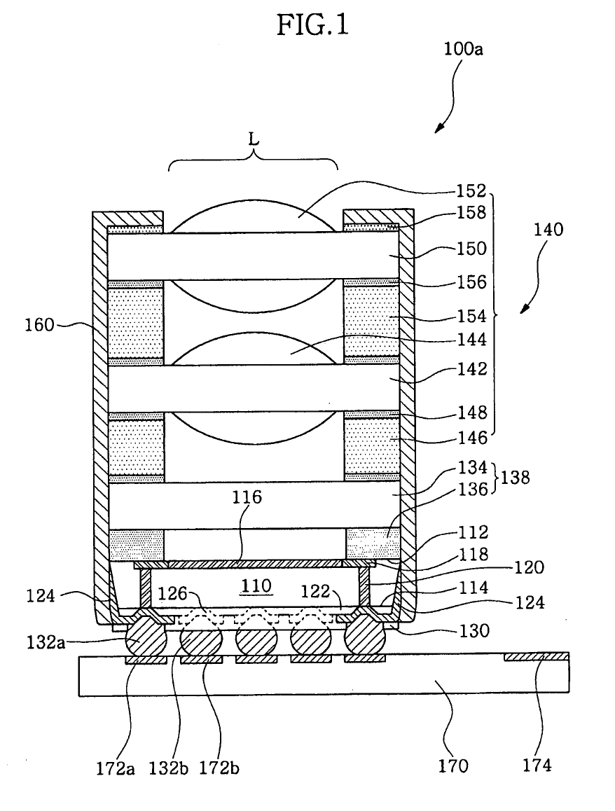

Hereinafter, exemplary embodiments of a camera module according to aspects of the present invention will be described. FIG. 1 is a cross-sectional view of such an exemplary embodiment of a camera module according to aspects of the invention.

Referring to FIG. 1, a camera module 100a includes an image sensor chip 110 having an active plane 112 and a backside 114. The image sensor chip 110 may be formed on a chip wafer, such as a silicon wafer. Specifically, it will be understood that the chip wafer is divided into individual chips by performing a passivation process and a sawing process. In this case, the image sensor chip 110 may be manufactured to have a width that gradually narrows from the active plane 112 to the backside 114.

An image sensing region 116 having a plurality of image sensing devices and chip pads 118 electrically connected to the image sensing devices and disposed around the image sensing region 116 may be formed on the active plane 112. The image sensing devices may include CMOS or CCD image sensing devices. The chip pads 118 may input or output an external electric signal to or from the image sensor chip 110. The number and shape of chip pads 118 may be configured according to type and characteristics of the image sensor chip 110. The chip pads 118 may be electrically connected to the image sensing devices through a redistribution structure (not shown) on the active plane 112. According to other exemplary embodiments, the chip pads 118 may be disposed to be separated from the image sensing region 116 and electrically connected to the image sensing region 116 through bonding wires.

Meanwhile, the chip pads 118 include power supply voltage chip pads, input/output signal chip pads, and ground chip pads. In FIG. 1, for convenience of description, only the ground chip pads are shown by omitting the power supply voltage chip pads and the input/output signal chip pads. The ground chip pads 118 may shield electromagnetic waves generated in the image sensor chip 110 or entering from an outside source.

Vias 120 passing through the image sensor chip 110 may be disposed between the active plane 112 and the backside 114. The vias 120 may be electrically connected to the chip pads. Some of the vias 120 may be electrically connected to the ground chip pads 118. The vias 120 may be formed of a metal, for example, copper or aluminum.

A first lower insulating layer 122 may be formed on the backside 114 of the image sensor chip 110. The first lower insulating layer 122 may be formed of a passivation material, for example, Benzo-Cyclo-Butene (BCB), Poly-Benzo-Oxazole (PBO), polyimide, epoxy, silicon oxide, or silicon nitride.

On the first lower insulating layer 122, a redistribution structure 126 may be disposed to fill holes exposing the vias 120 electrically connected to the power supply voltage chip pads and the input/output signal chip pads. On the other hand, ground wirings 124 are formed to fill the holes exposing the vias 120 electrically connected to the ground chip pads 118. In this case, the ground wirings 124 may be formed extending from sidewalls of the image sensor chip 110 to lower portions of the ground chip pads 118 of the backside 114 in a unified manner. The sidewalls may be inclined. The ground wirings 124 formed on a lower portion of the backside 114 may be formed at the same level as the redistribution structure 126. The redistribution structure 126 and the ground wirings 124 may be formed of the same conductive layer, for example, at least one selected from the group of titanium, chrome, titanium tungsten, aluminum, nickel, copper, and silver.

A second lower insulating layer 130 may be formed on a lower portion of the first lower insulating layer 122 having the redistribution structure 126 and the ground wirings 124. The second lower insulating layer 130 may perform the same function as the first lower insulating layer 122, and may be formed of a material layer included in the first lower insulating layer 122. Ground conductive balls 132a and signal conductive balls 132b for electrically connecting the ground wirings 124 and the redistribution structure 126 may be formed to pass through the second lower insulating layer 130. The conductive balls 132a and 132b may be formed of materials exhibiting strong adhesion to the redistribution structure 126 and the ground wirings 124, low contact resistance, and high durability.

Meanwhile, a filter structure 138 may be formed on the active plane 112 of the image sensor chip 110. In this case, the filter structure 138 may have substantially the same width as the active plane 112 of the image sensor chip 110. The filter structure 138 may include a filter substrate 134 and an adhesion layer 136. The adhesion layer 136 may include an opening exposing the image sensing region 116. The filter substrate 134 may be disposed on the adhesion layer 136 and separated from the image sensing region 116. The filter substrate 134 may be transparent and may include an infrared filter layer (not shown) for filtering infrared light incident on the camera module 100a, and an anti-reflective layer (not shown). The adhesion layer 136 may be formed of a photosensitive material, for example, BCB or polyimide. The adhesion layer 136 may have an appropriate height, such that the filter substrate 134 may be separated by a predetermined space.

A lens structure 140 may be stacked on the filter structure 138. In this case, the lens structure 140 may have substantially the same width as the active plane 112 of the image sensor chip 110. To focus light on the image sensing region 116, the lens structure 140 may have a light detector L1 including at least one lens overlapping with the image sensing region 116. The light detector L1 is formed on a path along which external incident light is incident on the image sensing region 116. For example, as shown in FIG. 1, the lens structure 140 may include first and second transparent lens substrates 142 and 150 separated from the filter structure 138. The first and second lens substrates 142 and 150 may be also separated from each other and stacked. A first spacer 146 may be disposed between the filter structure 138 and the first lens substrate 142 in order to separate the first structure 138 from the first lens substrate 142. The first spacer 146 does not overlap the image sensing region 116. Likewise, a second spacer 154 may be disposed between the first lens substrate 142 and the second lens substrate 150 in order to separate the first lens substrate 142 from the second lens substrate 150. The second spacer 154 does not overlap the image sensing region 116. First and second lenses 144 and 152 may be disposed on surfaces of the lens substrates 142 and 150. As described above, the purpose of an arrangement in which the first and second lens substrates 142 and 150 are separated from each other is to adjust a focal length between the image sensing region 116 and from the first and second lenses 144 and 152. Consequently, the light detector L1 may be configured with the lenses 144 and 152 overlapping a region of the lens substrates 142 and 150. Meanwhile, adhesion layers 148 and 156 may be formed to improve adhesion between the lens substrates 142 and 150 and the spacers 146 and 154.

A conductive housing 160 may be disposed to cover an outer wall of the lens structure 140 excluding the light detector L and sidewalls of the filter structure 138. The outer wall of the lens structure 140 excluding the light detector L is configured with an upper surface of the second lens substrate 150 around the second lens 152, the outer walls of the lens substrates 142 and 150, and the spacers 146 and 154. In this case, the conductive housing 160 is extended and formed on the ground wirings 124 formed on the sidewalls of the image sensor chip 110. The conductive housing 160 may be formed to a thickness of 0.3 μm to 1.0 μm, in this embodiment, and configured with materials included in the ground wirings 124. In addition, an adhesion promotion layer 158 may be formed between the upper surface of the second lens substrate 150 and the conductive housing 160. In this case, the adhesion promotion layer 158 may be formed in a range that does not overlap the image sensing region 116. The adhesion promotion layer 158 may be formed of photosensitive polymer, for example, BCB or polyimide.

Accordingly, the camera module 100a includes the image sensor chip 110, the filter structure 138, the lens structure 140, the conductive housing 160, and the ground wirings 124 electrically connected to the conductive housing 160.

The camera module 100a may be electrically connected to external pads 172a and 172b of a circuit board 170 through the conductive balls 132a and 132b. In this case, the ground conductive balls 132a and the signal conductive balls 132b may be respectively connected to the external ground pads 172a and the external signal pads 172b. The circuit board 170 may be a printed circuit board, for example, a rigid or flexible circuit board. An external connector 174 may be disposed on one side of the circuit board 170 and the external pads 172a and 172b may be electrically connected to the external connector 174.

According to exemplary embodiments, electromagnetic waves incident on the camera module 100a may be reemitted along a wiring connected to the conductive housing 160, the ground wirings 124, and the ground conductive balls 132a, without affecting the image sensor chip 110, etc., thereby eliminating EMI in the camera module. The conductive housing 160 does need to extend to the backside 114 of the image sensor chip 110 for electrical connection to the ground conductive balls 132a, thereby securing a large contact area through the ground wirings 124.

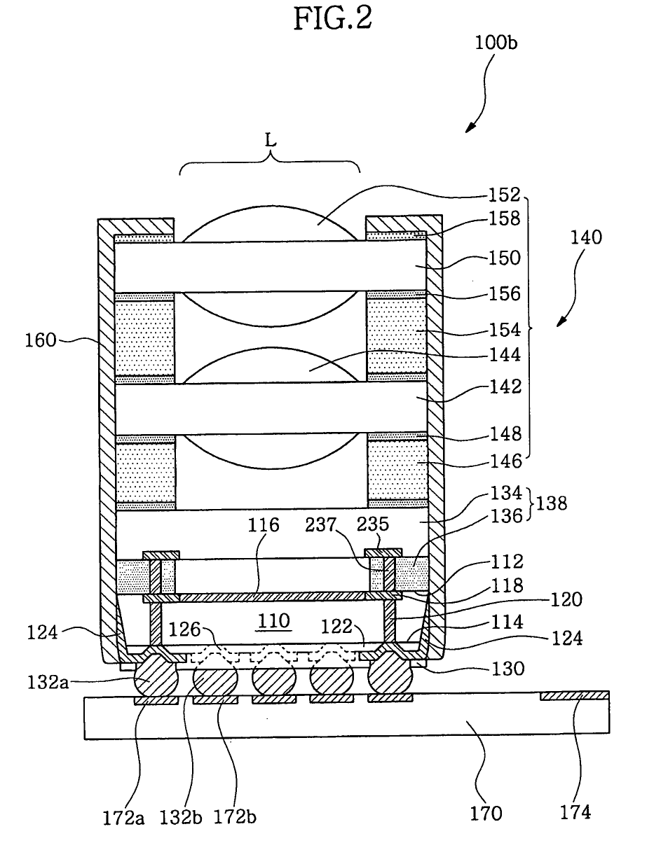

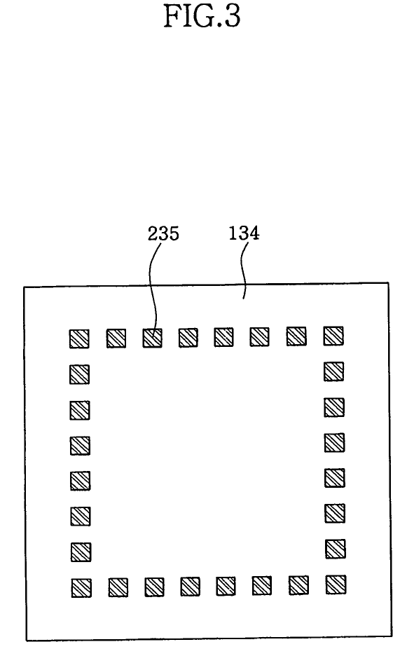

Exemplary embodiments of a camera module will be described with reference to FIGS. 2 and 3. FIG. 2 is a cross-sectional view of an embodiment of a camera module according to other aspects of the invention, and FIG. 3 is a plan view of an embodiment of a transparent filter substrate. The exemplary embodiments shown in FIGS. 2 and 3 are similar to those shown in FIG. 1 except for the filter structure.

The camera module 100b may include a filter structure 138 interposed between the lens structure 140 and the image sensor chip 110 having the ground wirings 124 disposed on inclined sidewalls extending from the backside 114. As described in the exemplary embodiments of FIG. 1, the filter structure 138 may include the adhesion layer 136 having the opening exposing the image sensing region 116, and the filter substrate 134 disposed on the adhesion layer 136 and separated from the image sensing region 116 by a predetermined space.

In this case, the filter substrate 134 may include filter circuits 235 disposed thereon. The filter circuits 235 may be formed in a range in which the image sensing region 116 of the image sensor chip 110 is not covered. The filter circuits 235 may be electrically connected to the chip pads 118 formed on the active plane 112 by plugs 237 passing through the adhesion layer 136. The filter circuits 235 may be formed of pads having the same function as the chip pads 118. Although not shown in FIG. 3, the pads may be connected in series or parallel. According to other exemplary embodiments, the filter circuits 235 may be formed of circuit elements, for example, transistors, etc. According to the above exemplary embodiments, circuits are formed on one surface of the filter substrate 134, thereby providing a circuit wiring margin and increasing integration of the camera module 100b.

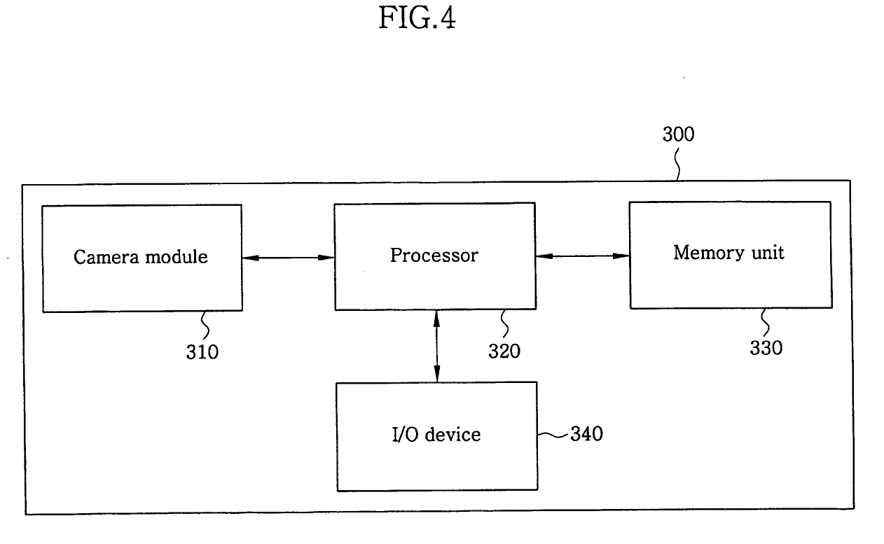

FIG. 4 is a schematic block diagram of an embodiment of an electronic system adopting the camera module according to aspects of the present invention.

Referring to FIG. 4, an electronic system 300 includes a camera module 310, a processor 320, a memory unit 330, and an input/output device 340. The camera module 310 may capture images. The processor 320 may process data for the image captured by the camera module 310. The memory unit 330 may store the image data. The image data may be communicated to the processor 320. The input/output device 340 may communicate with the processor 320. In this case, the electronic system 300 may be a cellular phone, a digital camera, a digital video camera, a portable notebook computer, etc.

The camera module 310 may include the camera modules described according to an exemplary embodiment of the invention. Although not shown in FIG. 4, an image signal captured by the camera module 310 may be converted into digital data. The camera module 310 may include a signal processing circuit, for example, an analog-to-digital (A/D) converting circuit, etc. The signal processing circuit may convert the image signal into the digital image data. The digital image data may be transmitted to the processor 320. In a single chip, the camera module 310 may further include an image processor connected to the camera modules.

The processor 320 may perform various data processes for the digital image data. In this case, the digital image data is temporarily stored in a rewritable semiconductor memory, for example, a DRAM or a nonvolatile memory, such that the digital image data may be processed. The digital image data may be stored in the memory unit 330. The memory unit 330 may include a rewritable semiconductor memory, for example, a DRAM or a nonvolatile memory.

The electronic system 300 may exchange image data with another electronic system, such as a personal computer or computer network, through the input/output device 340. For example, the image processed in the processor 320 may be output to an external device connected to the input/output device 340, for example, an external display, personal computer, printer, etc. The input/output device 340 may provide the image data to a peripheral bus line, high-speed transmission line, or radio transmission/reception antenna of a computer or cellular phone. Communication of the image data between the camera module 310, the processor 320, the memory unit 330, and the input/output device 340 may be performed using conventional computer bus architectures.

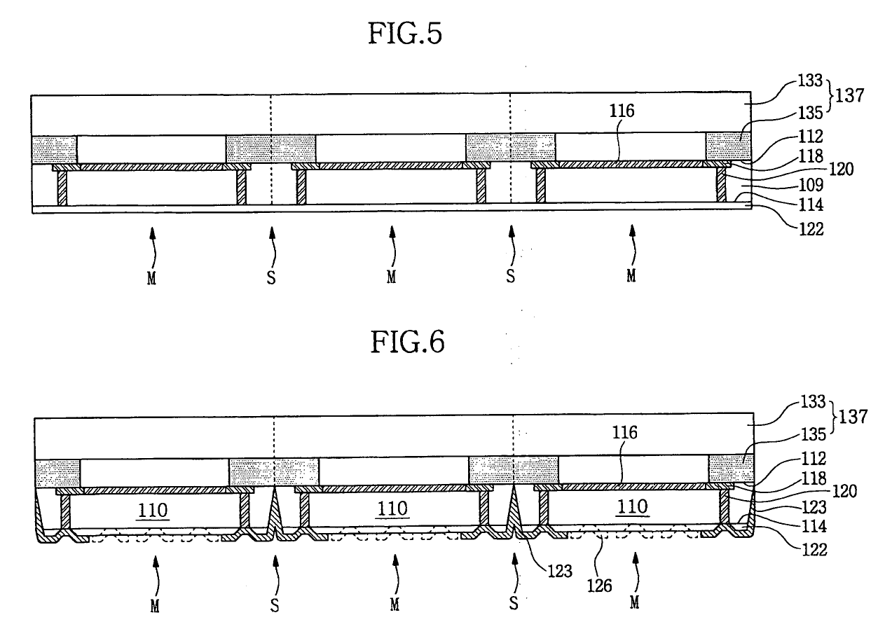

Next, a method of manufacturing a camera module according to exemplary embodiments will be described with reference to FIGS. 1 and 5 to 6. FIGS. 5 and 6 depict an exemplary embodiment of a method of manufacturing a camera module according to aspects of the invention.

Referring to FIG. 5, a chip wafer 109 having the active plane 112 and the backside 114 is provided. The chip wafer 109 has horizontally distinguished main regions M and sawing regions S adjacent thereto. One side of the main regions M is the active plane 112 and the other side is the backside 114. The chip wafer 109 may be a silicon based wafer.

The image sensing regions 116 including a plurality of image sensing devices, and the chip pads 118 electrically connected to the image sensing devices and disposed around each of the image sensing regions 116, may be formed on the active plane 112 of the main regions M. The image sensing devices may include CMOS or CCD image sensing devices. The number and shape of chip pads 118 may be variously configured according to type or characteristics of an image sensor chip to be formed later. The chip pads 118 may be electrically connected to the image sensing devices through a redistribution structure (not shown) on the active plane 112. In this case, the redistribution structure may be formed using electro/electroless plating. Of course, the redistribution structure may be formed using sputtering, polishing, or photolithography. In other exemplary embodiments, the chip pads 118 may be separated from and electrically connected to the image sensing regions 116 by wire bonding.

The chip pads 118 include power supply voltage chip pads, input/output signal chip pads, and ground chip pads. In FIG. 5, for convenience of description, only the ground chip pads are shown while the power supply voltage chip pads and the input/output signal chip pads are omitted.

The vias 120 passing through the chip wafer 109 of the main regions M may be formed between the active plane 112 and the backside 114. The vias 120 may be electrically connected to the chip pads. Some of the vias 120 may be electrically connected to the ground chip pads 118. The vias 120 may be formed of a metal, for example, copper or aluminum.

The first lower insulating layer 122 may be wholly formed on the backside 114 of the chip wafer 109, as in the present embodiment. The first lower insulating layer 122 may be formed of a passivation material, for example, BCB, PBO, polyimide, epoxy, silicon oxide, or silicon nitride.

A preliminary filter structure 137 is attached to the active plane 112 of the chip wafer 109. In this case, the preliminary filter structure 137 may have substantially the same width as the active plane 112 of the chip wafer 109. The preliminary filter structure 137 may include an adhesion layer 135 having openings exposing the image sensing regions 116, and a filter wafer 133 disposed on the adhesion layer 135 and separated from the image sensing regions 116 by a predetermined space. The filter wafer 133 is a transparent substrate that may include an infrared filter layer (not shown) and an anti-reflective layer (not shown). The adhesion layer 135 may be formed of photosensitive polymer, for example, BCB or polyimide. The adhesion layer 135 has an appropriate height, such that the filter wafer 133 may be separated by a predetermined space.

In other exemplary embodiments, the preliminary filter structure 137 may be formed of the adhesion layer 135 having the openings and the filter wafer 133 formed on the adhesion layer 135, such as the filter structure 138 shown in FIGS. 2 and 3. In such a case, the filter wafer 133 may include filter circuits disposed on a surface facing the active planes 112 of the main regions M. The filter circuits may be formed in a range within which the image sensing regions 116 and the sawing regions S do not overlap. The filter circuits may be electrically connected to the chip pads 118 by plugs passing through the adhesion layer 135. The filter circuits may be formed of pads having the same function as the chip pads 118. Although not shown in FIG. 3, the pads may be connected in series or parallel. In other exemplary embodiments, the filter circuits may be formed of circuit elements, for example, transistors, etc.

Referring to FIG. 6, the image sensor chips 110 whose sidewalls are exposed are formed by cutting the backside 114 corresponding to the sawing regions S. The sidewalls may be inclined to have a width that gradually narrows from the active plane 112 of the image sensor chip 110 to the backside 114 of the image sensor chip 110. To form the inclined sidewalls, the backside 114 may be cut using a dicing process, such as a dicing process known in the art. Even when the dicing process is performed, the image sensor chips 110 are attached using the adhesion layer 135 without being individually separated.

After the holes exposing the vias 120 electrically connected to the power supply voltage chip pads and the input/output signal chip pads are formed on the first lower insulating layer 122, the redistribution structure 126 filling the holes may be formed. Simultaneously, after the holes exposing the vias 120 electrically connected to the ground chip pads 118 are formed, ground wiring layers 123 filling the holes may be formed. The ground wiring layers 123 may be formed extending uniformly from the sidewalls to the lower portions of the ground chip pads 118 of the backsides 114. In this case, the ground wiring layers 123 may be formed between the facing sidewalls of the neighboring image sensor chips 110. The ground wiring layers 123 formed on lower portions of the backsides 114 may be formed at the same level as the redistribution structure 126. The ground wiring layers may be formed extending from the sidewalls of the image sensor chips 110 to the ground chip pads 118 in a process of manufacturing the redistribution structure 126 without forming the ground wirings in an additional process.

The redistribution structure 126 and the ground wiring layers 123 may be formed of the same conductive material, for example, at least one of titanium, chrome, titanium tungsten, aluminum, nickel, copper, and silver. The redistribution structure 126 and the ground wiring layers 123 may be formed by a sputtering, evaporation deposition, electro/electroless plating, or photolithography process. The image sensor chips 110 may have the slightly inclined sidewall with respect to the backside 114, such that the ground wiring layers 123 may be formed at lower edges of the image sensor chips 110 without any disconnection. In these exemplary embodiments, an example of the ground wiring layers 123 connected between the neighboring image sensor chips 110 without any separation has been described. Alternatively, the ground wiring layers 123 may be separated from each other between the neighboring image sensor chips 110. The ground wiring layers 123 may be regarded as ground wirings.

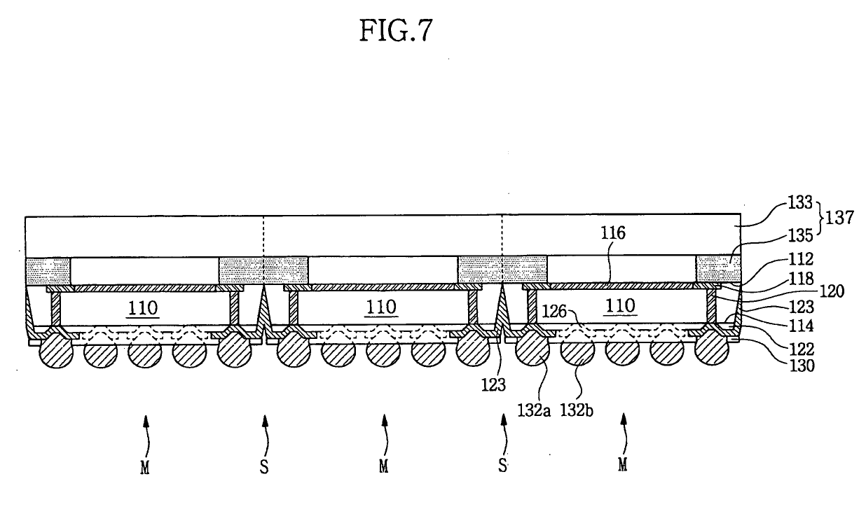

Referring to FIG. 7, the second lower insulating layer 130 may be formed on a lower portion of the first lower insulating layer 122. The first lower insulating layer 122 may have the redistribution structure 126 and the ground wiring layers 123. The second lower insulating layer 130 may be formed of a passivation material, for example, Benzo-Cyclo-Butene (BCB), Poly-Benzo-Oxazole (PBO), polyimide, epoxy, silicon oxide, or silicon nitride. Next, the ground conductive balls 132a and the signal conductive balls 132b electrically connected to the ground wiring layers 123 and the redistribution structure 126 may be formed to pass through the second lower insulating layer 130. The conductive balls 132a and 132b may be formed of materials exhibiting strong adhesion to the redistribution structure 126 and the ground wirings 124, low contact resistance, and high durability.

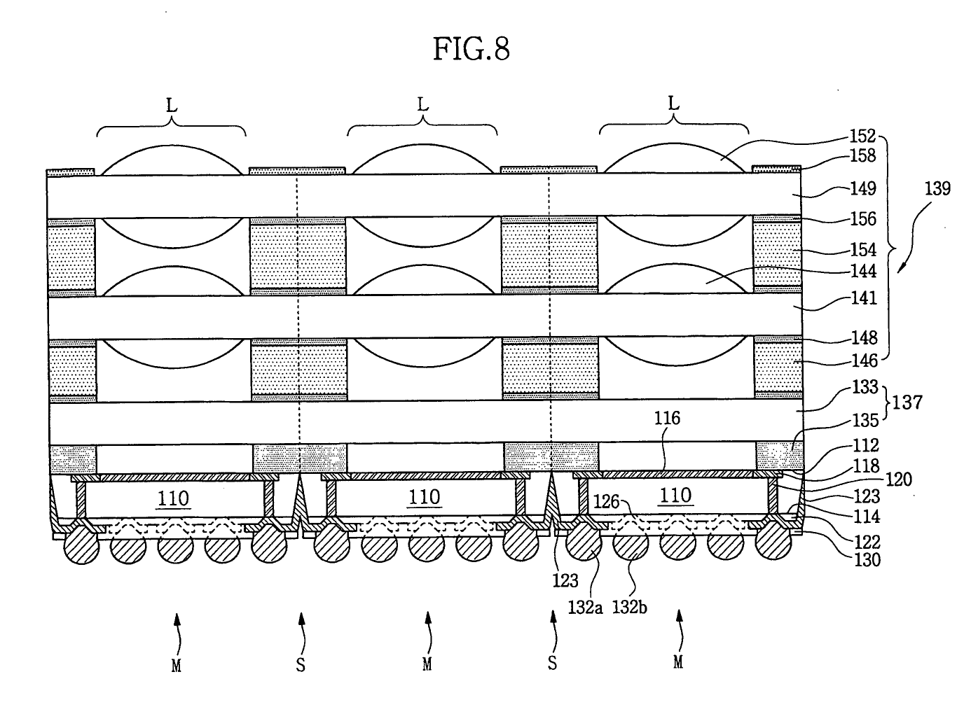

Referring to FIG. 8, a preliminary lens structure 139 may be vertically stacked on the preliminary filter structure 137. In this case, the preliminary lens structure 139 may have substantially the same width as the preliminary filter structure 137. The preliminary lens structure 139 may have light detectors L disposed horizontally and respectively corresponding to the image sensing regions 116. Each of the light detectors L may include at least one lens overlapping with each of the image sensing regions 116. For example, as shown in FIG. 8, the preliminary lens structure 139 may include first and second transparent lens wafers 141 and 149 separated from the preliminary filter structure 137. The first and second lens wafers 141 and 149 may be separated from each other and stacked. In this case, a first spacer 146 may be disposed between the preliminary filter structure 137 and the first lens wafer 141 in order to separate the preliminary filter structure 137 and the first lens wafer 141 from each other. The first spacer 146 does not overlap the image sensing regions 116. Likewise, a second spacer 154 may be disposed between the first and second lens wafers 141 and 149 in order to separate the first and second lens wafers 141 and 149 from each other. The second spacer 154 does not overlap the image sensing regions 116.

First and second lenses 144 and 152 may be disposed on surfaces of the lens wafers 141 and 149. On the lens wafers 141 and 149, the lenses are horizontally disposed. As described above, the lenses 144 and 152 disposed on each layer may be disposed to vertically overlap the image sensing region 116. Consequently, the light detectors L may be formed of the lenses 144 and 152 and a region of the lens wafers 141 and 149 overlapped by the lenses 144 and 152. Adhesion layers 148 and 156 may be formed to improve adhesion between the lens wafers 141 and 149 and the spacers 146 and 154.

In addition, an adhesion promotion layer 158 may be formed on the upper surface of the second lens wafer 149. The adhesion promotion layer 158 may be formed in a range that does not overlap the image sensing region 116. The adhesion promotion layer 158 may be formed of photosensitive polymer, for example, BCB or polyimide.

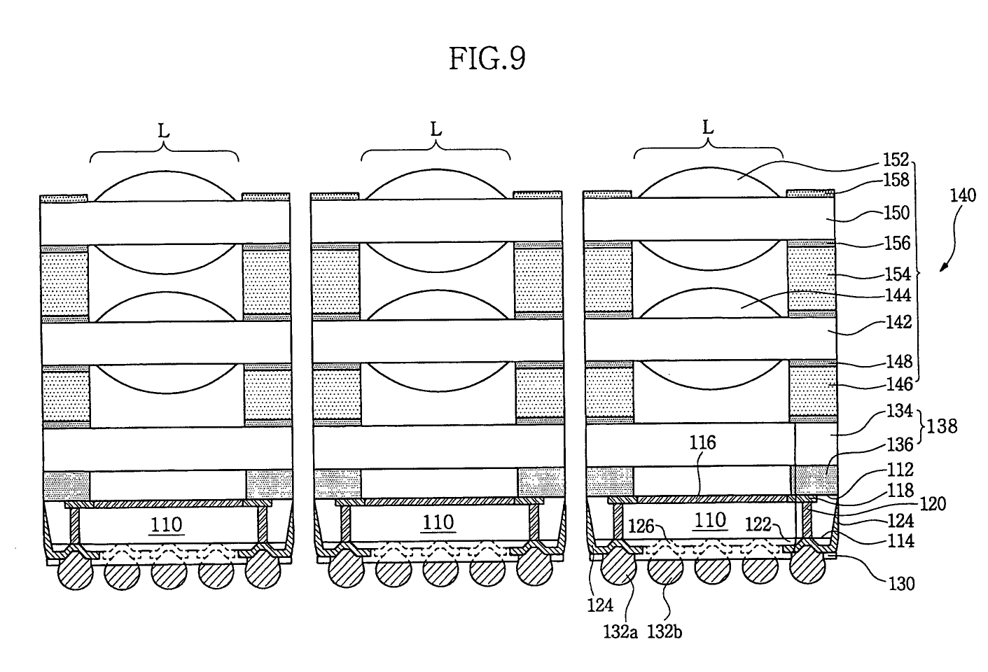

Referring to FIG. 9, the preliminary filter structure 137 and the preliminary lens structure 139 are cut along an extension line of the sawing region S. Consequently, the filter structure 138 and the lens structure 140 are formed. The filter structure 138 and the lens structure 140 may be sequentially stacked on each of the image sensor chips 110. The filter structure 138 may include the adhesion layer 136. The adhesion layer 136 may have an opening exposing the image sensing region 116. The filter substrate 134 may be disposed on the adhesion layer 136 and cut and separated from the filter wafer 133. The lens structure 140 may include the first and second lens substrates 142 and 150. The first and second lens substrates 142 and 150 may be cut and separated from the first and second lens wafers 141 and 149, respectively. The first and second lenses 144 and 152, and the first and second spacers 146 and 154 may be disposed on lower portions of the first and second lens substrates 142 and 152, respectively. The ground wiring layers 123 are also cut and the ground wirings 124 may be residual on sidewalls of the individually separated image sensor chips 110.

Consequently, the filter structure 138 and the lens structure 140 may be self-aligned with the image sensor chips 110, and formed to be substantially the same size as the image sensor chips 110, thereby reducing the size of the camera module.

Referring again to FIG. 1, the conductive housing 160 may be disposed to cover the outer wall of the lens structure 140, excluding the light detector L and the sidewalls of the filter structure 138. The outer wall of the lens structure 140 excluding the light detector L is configured with the upper surface of the second lens substrate 150 around the second lens 152, the outer walls of the lens substrates 142 and 150, and the spacers 146 and 154. In this case, the conductive housing 160 is extended and formed on the ground wirings 124 disposed on the sidewalls of the image sensor chip 110.

The conductive housing 160 may be formed using sputtering, evaporation deposition, or electro/electroless plating. The above deposition process may be performed using a mask pattern covering the backside 114 and the light detector L of the lens structure 140. Accordingly, the conductive housing 160 is not formed on the backside 114 and the light detector L. Consequently, the conductive housing 160 may be formed to a thickness of 0.3 μm to 1.0 μm, in this embodiment. The conductive housing 160 may be thinly manufactured using the above-described deposition process. On the other hand, the conductive housing 160 may be configured with material layers included in the ground wiring layers 123.

Accordingly, the camera module 100 including the image sensor chip 110, the filter structure 138, the lens structure 140, the conductive housing 160, and the ground wirings 124 electrically connected to the conductive housing 160 is completed.

In these exemplary embodiments, a process of forming the ground wirings 124 for the image sensor chips 110 in a state in which they are not individually separated on the filter wafer 133 has been described. The process of forming the ground wirings is not limited to the above-described exemplary embodiments, but may be performed by various methods. For example, after the image sensor chips are individually separated by the sawing process without attaching the chip wafer on the filter wafer 133, the ground wirings, the filter structure, and the lens structure may be formed on each image sensor chip.

According to exemplary embodiments, a ground wiring may be formed extending from a sidewall of an image sensor chip to a backside. Therefore, a lens structure formed on the image sensor chip and a conductive housing covering the image sensor chip can be easily formed on the ground wiring disposed on the sidewall. Consequently, electromagnetic waves input to a camera module including the image sensor chip and the lens structure can be reemitted from the camera module without affecting the image sensor chip, etc., thereby preventing EMI from occurring in the camera module.

The ground wiring may be formed by the same process as a redistribution structure formed on the backside. The ground wiring may be formed by a single process. The conductive housing may be formed by a deposition process. Therefore, the conductive housing can be made thin so that the size of the camera module can be reduced.

While exemplary embodiments have been disclosed herein, it should be understood that other variations may be possible. Such variations are not to be regarded as a departure from the spirit and scope of the present application, and all such modifications are intended to be included within the scope of the following claims.

What is claimed is:

1. A camera module comprising:
an image sensor chip having an active plane and a backside;
a ground wiring extending from a sidewall of the image sensor chip to the backside;
a lens structure having a light detector with at least one lens stacked on the active plane; and
a conductive housing extending to the ground wiring along with an outer wall of the lens structure excluding the light detector.

2. The camera module of claim 1, wherein the sidewall of the image sensor chip is inclined to have a width that gradually narrows from the active plane to the backside.

3. The camera module of claim 1, wherein the image sensor chip has chip pads on the active plane, and vias electrically connected to the chip pads through the image sensor chip, and
wherein the ground wiring is formed to be electrically connected to some of the vias.

4. The camera module of claim 1, further comprising:
conductive balls disposed on lower portions of the ground wirings formed on the backsides of the image sensor chips.

5. The camera module of claim 1, further comprising:
a redistribution structure formed on backsides of image sensor chips,
wherein the ground wiring of the backside is formed at the same level as the redistribution structure.

6. The camera module of claim 1, further comprising:
an adhesion layer having an opening formed on the active plane; and
a filter substrate disposed on the adhesion layer,
wherein the filter substrate has a filter circuit electrically connected to a circuit formed on the active plane.

7. A method of manufacturing a camera module, comprising:
forming an image sensor chip having an active plane and a backside;
forming a ground wiring extending from a sidewall of the image sensor chip to the backside;
forming a lens structure having a light detector with at least one lens stacked on the active plane; and
forming a conductive housing extending to the ground wiring along with an outer wall of the lens structure excluding the light detector.

8. The method of claim 7, wherein the sidewall of the image sensor chip is inclined to have a width that gradually narrows from the active plane to the backside.

9. The method of claim 7, wherein the image sensor chip has chip pads on the active plane, and vias electrically connected to the chip pads through the image sensor chip, and
wherein the ground wiring is formed to be electrically connected to some of the vias.

10. The method of claim 7, further comprising:
forming at least one conductive ball on a lower portion of the ground wiring formed on the backside before forming the lens structure.

11. The method of claim 7, wherein a redistribution structure is formed on the backside while forming the ground wiring.

12. The method of claim 7, wherein the conductive housing is formed of at least one material selected from the group consisting of titanium, chrome, titanium tungsten, aluminum, nickel, copper, and silver.

13. The method of claim 7, further comprising:
forming an adhesion layer having an opening on the active plane before forming the lens structure; and
forming a filter substrate on the adhesion layer,
wherein the filter substrate has a filter circuit electrically connected to a circuit formed on the active plane.

14. A method of manufacturing a camera module, comprising:
providing a chip wafer having an active plane including main regions and sawing regions, and a backside;
forming a preliminary filter structure onto the active plane;
forming image sensor chips whose sidewalls are exposed by cutting the backside corresponding to the sawing regions;
forming ground wirings extending from the sidewalls of the image sensor chips to backsides of the image sensor chips;
forming a preliminary lens structure covering active planes of the image sensor chips and having light detectors with stacked lenses respectively overlapping the main regions of the image sensor chips;
separating the image sensor chips by cutting the preliminary filter structure and the preliminary lens structure, and forming filter structures and lens structures that are sequentially stacked on each of the image sensor chips; and
forming conductive housings extending to outer walls of the lens structures, excluding the light detectors, the filter structures, and the ground wirings.

15. The method of claim 14, wherein the exposed sidewall of each of the image sensor chips is inclined to have a width that gradually narrows from the active plane to the backside.

16. The method of claim 14, wherein each of the image sensor chips has chip pads on the active plane, and vias electrically connected to the chip pads through the image sensor chip, and
wherein each ground wiring is formed to be electrically connected to some of the vias.

17. The method of claim 14, further comprising:
forming conductive balls on lower portions of the ground wirings formed on the backsides of the image sensor chips before forming the preliminary lens structure.

18. The method of claim 14, wherein a redistribution structure is formed on the backsides of the image sensor chips while forming the ground wirings.

19. The method of claim 14, wherein the preliminary filter structure has an adhesion layer with an opening on the active plane, and a transparent filter wafer on the adhesion layer,
wherein the transparent filter wafer has filter circuits electrically connected to circuits formed on the active planes.

20. An electronic system comprising:
a camera module that captures an image;
a processor that processes the captured image;
a memory unit that stores the processed image data; and
an input/output device that communicates with the processor,
wherein the camera module includes:
an image sensor chip having an active plane and a backside;
a ground wiring extending from a sidewall of the image sensor chip to the backside;
a lens structure having a light detector with at least one lens stacked on the active plane; and
a conductive housing extending to the ground wiring along with an outer wall of the lens structure excluding the light detector.
